(19) United States
(12) Patent Application Publication
(10) Pub. No.: US 2025/0392329 A1
(43) Pub. Date: Dec. 25, 2025

(54) RADIO FREQUENCY MODULE

(71) Applicant: Murata Manufacturing Co., Ltd., nagaokakyo-shi (JP)

(72) Inventors: Takeshi KOGURE, Nagaokakyo-shi (JP); Kazuaki Deguchi, Nagaokakyo-shi (JP); Ikumi Tokuda, nagaokakyo-shi (JP); Toshiki Matsui, Nagaokakyo-shi (JP)

(21) Appl. No.: 19/310,112

(22) Filed: Aug. 26, 2025

Related U.S. Application Data
(63) Continuation of application No. PCT/JP2023/045542, filed on Dec. 19, 2023.

(30) Foreign Application Priority Data
Mar. 6, 2023 (JP) 2023-033791

(51) Int. Cl. H04B 1/00; H03F 1/02; H03F 1/32; H03F 3/24; H04B 1/40

(52) U.S. Cl. CPC H04B 1/0057; H03F 1/0227; H03F 1/3241; H03F 3/245; H04B 1/40; H03F 2200/102; H03F 2200/451

(57) ABSTRACT

A radio frequency module is provided that includes first and second power amplifiers that amplify a WLAN signal in a first frequency band, a voltage generation circuit that generates multiple discrete voltages, a supply modulator connected between the power amplifier and the voltage generation circuit and selectively outputs one of the multiple discrete voltages, another supply modulator connected between the power amplifier and the voltage generation circuit and selectively outputs one of the multiple discrete voltages, and first and second integrated circuits that each include a switch of one of the supply modulators. A distance between the first power amplifier and the first integrated circuit is shorter than a distance between the first power amplifier and the second integrated circuit, and a distance between the second power amplifier and the second integrated circuit is shorter than a distance between the second power amplifier and the first integrated circuit.

### REFERENCE TO RELATED APPLICATIONS

This application is a continuation of International Application No. PCT/JP2023/045542, filed Dec. 19, 2023, which claims priority to Japanese Patent Application No. 2023-033791, filed Mar. 6, 2023, the contents of each of which are hereby incorporated by reference in their entireties.

### TECHNICAL FIELD

The exemplary aspects of the present disclosure relate to a radio frequency (RF) module.

### BACKGROUND

Japanese Unexamined Patent Application Publication No. 2019-140671 discloses a circuit for amplifying a 2.4-GHz-band signal and a 5-GHz-band signal of a wireless local area network (WLAN).

Currently, in WLAN systems, when the modulation bandwidth (channel bandwidth) and the bit rate of the digital modulation scheme are increasing, it is desirable to supply voltage to the amplifier in the digital ET (Envelope Tracking) mode.

However, when the digital ET is applied to circuits, such as that disclosed in Japanese Unexamined Patent Application Publication No. 2019-140671, there is a concern that, depending on the arrangement of the amplifier and the digital ET tracker circuit, the efficiency of the digital ET tracker circuit will deteriorate and the power consumption will increase.

### SUMMARY OF THE INVENTION

Accordingly, the exemplary aspects of the present disclosure provide a radio frequency (RF) module configured to suppress efficiency degradation while restraining an increase in power consumption.

In an exemplary aspect, a radio frequency module is provided that includes: a first power amplifier connected to a first antenna and configured to amplify a wireless local area network signal in a first frequency band; a second power amplifier connected to a second antenna different from the first antenna and configured to amplify the wireless local area network signal in the first frequency band; a voltage generation circuit configured to generate a plurality of discrete voltages; a first supply modulator connected between the first power amplifier and the voltage generation circuit and configured to select and output at least one discrete voltage of the plurality of discrete voltages to the first power amplifier; a second supply modulator connected between the second power amplifier and the voltage generation circuit and configured to select and output at least one discrete voltage of the plurality of discrete voltages to the second power amplifier; a first integrated circuit including at least one switch included in the first supply modulator; and a second integrated circuit including at least one switch included in the second supply modulator. In this aspect, wherein a distance between the first power amplifier and the first integrated circuit is shorter than a distance between the first power amplifier and the second integrated circuit, and a distance between the second power amplifier and the second integrated circuit is shorter than the distance between the second power amplifier and the first integrated circuit.

Additionally, a radio frequency module is provided that includes a first power amplifier connected to a first antenna and configured to amplify a wireless local area network signal in a first frequency band; a second power amplifier connected to a second antenna different from the first antenna and configured to amplify the wireless local area network signal in the first frequency band; a voltage generation circuit configured to generate a plurality of discrete voltages; a first supply modulator connected between the first power amplifier and the voltage generation circuit and configured to select and output at least one discrete voltage of the plurality of discrete voltages to the first power amplifier; a second supply modulator connected between the second power amplifier and the voltage generation circuit and configured to select and output at least one discrete voltage of the plurality of discrete voltages to the second power amplifier; a first integrated circuit including at least one switch included in the first supply modulator; and a second integrated circuit including at least one switch included in the second supply modulator. In this aspect, a distance between the first power amplifier and the first integrated circuit is shorter than one-half of a distance between the first power amplifier and the second power amplifier, and a distance between the second power amplifier and the second integrated circuit is shorter than one-half of the distance between the first power amplifier and the second power amplifier.

According to the radio frequency modules of the exemplary aspects of the present disclosure, efficiency degradation is suppressed while an increase in power consumption is also limited.

### BRIEF DESCRIPTION OF DRAWINGS

FIG. 1A is a graph illustrating an example of the transition of a power supply voltage in an APT (Average Power Tracking) mode.

FIG. 1B is a graph illustrating an example of the transition of the power supply voltage in an A-ET (Analog Envelope Tracking) mode.

FIG. 1C is a graph illustrating an example of the transition of the power supply voltage in a D-ET (Digital Envelope Tracking) mode.

FIG. 2 is a circuit configuration diagram of a radio frequency (RF) module and a communication device according to an exemplary embodiment.

FIG. 3 is a circuit configuration diagram of a tracker circuit according to the exemplary embodiment.

FIG. 4 is a module configuration diagram of the tracker circuit according to the exemplary embodiment.

FIG. 5 is a plan view of a first tracker module according to the exemplary embodiment.

FIG. 6 is a plan view of a second tracker module according to the exemplary embodiment.

FIG. 7 is a plan view of the RF module according to the exemplary embodiment.

### DETAILED DESCRIPTION OF EMBODIMENTS

Hereinafter, an embodiment of the present disclosure will be described in detail using the drawings. The embodiment described below is all illustrative of comprehensive or specific examples. The numerical values, shapes, materials, components, and component arrangement and connection forms discussed in the following embodiment are merely examples and are not intended to limit the present disclosure.

It is noted that each of the drawings is a schematic diagram that has been appropriately emphasized, omitted, or adjusted in scale to illustrate the exemplary aspects of the present disclosure. Therefore, the drawings are not necessarily depicted with strict accuracy and may differ from the actual shapes, positional relationships, and proportions. In each of the drawings, the same reference numerals are assigned to substantially identical configurations, and overlapping descriptions may be omitted or simplified.

In each of the following drawings, the x-axis and the y-axis are axes orthogonal to each other on a plane parallel to the main surface of a module substrate. Specifically, in the case where the module substrate has a rectangular shape in a plan view, the x-axis is parallel to a first side of the module substrate, and the y-axis is parallel to a second side, which is orthogonal to the first side of the module substrate. Additionally, the z-axis is an axis perpendicular to the main surface of the module substrate, the positive direction of which indicates an upward direction and the negative direction of which indicates a downward direction.

In the component arrangement of the exemplary aspects, the phrase “a plan view of the module substrate” refers to the orthogonal projection of an object or component onto the xy-plane as viewed from the positive side of the z-axis. The phrase “A overlaps with B in a plan view” can indicate that at least a portion of the region of A projected orthogonally onto the xy-plane overlaps with at least a portion of the region of B projected orthogonally onto the xy-plane. In addition, the phrase “A is arranged between B and C” can indicate that at least one of line segments connecting any point in B and any point in C passes through A.

In the component arrangement of the present disclosure, the phrase “the component is arranged on or in the substrate” includes both the arrangement of the component on the main surface of the substrate and the arrangement of the component within the substrate. Moreover, the phrase “the component is arranged on the main surface of the substrate” includes not only the arrangement of the component in contact with the main surface of the substrate but also the arrangement of the component above the main surface without direct contact with the main surface (for example, when the component is laminated or stacked on top of another component arranged in contact with the main surface). Additionally, it is acceptable that “the component is arranged on the main surface of the substrate” include the arrangement of the component in a recess formed in the main surface. It is also noted that the phrase “the component is arranged in the substrate” includes not only the encapsulation of the component within the module substrate but also cases where the entire component is arranged between two main surfaces of the substrate, with a portion of the component not covered by the substrate, as well as cases where only a portion of the component is arranged within the substrate.

In the circuit configuration of the present disclosure, the term “connected” refers not only to cases where direct connections are made by connection terminals and/or wiring conductors but also to cases where electrical connections are made with other circuit elements interposed therebetween. Moreover, the phrase “connected between A and B” can refer to being connected to both A and B between A and B.

Additionally, in the present disclosure, the phrase “component (element) A is arranged in series in path B” can indicate that both the signal input end and the signal output end of component (element) A are connected to wiring, an electrode, or a terminal forming path B.

Furthermore, in the component arrangement of the present disclosure, the phrase “A is arranged adjacent to B” represents that A and B are arranged in close proximity, specifically meaning that there are no other circuit components in the space where A faces B. In other words, “A is arranged adjacent to B” can indicate that, from any point on the surface of A facing B, each of multiple line segments extending in the normal direction of the surface reaches B without passing through any circuit components other than A and B. Here, circuit components refer to components including active elements and/or passive elements. That is, circuit components include active components including transistors, diodes, etc., as well as passive components including inductors, transformers, capacitors, resistors, etc., but they do not include electromechanical components including terminals, connectors, wiring, etc.

In the present disclosure, the term “terminal” can refer to the point at which a conductor within an element ends. Note that, when the impedance of a conductor between elements is sufficiently low, a terminal is interpreted not only as a single point but also as any point on the conductor between the elements or as the entire conductor.

Additionally, it is noted that terms indicating the relationship between elements, such as “parallel” and “vertical”, terms indicating the shape of elements, such as “rectangular shape”, and numerical ranges do not solely represent strict meanings but also encompass substantially equivalent ranges, including differences of a few percent, for example.

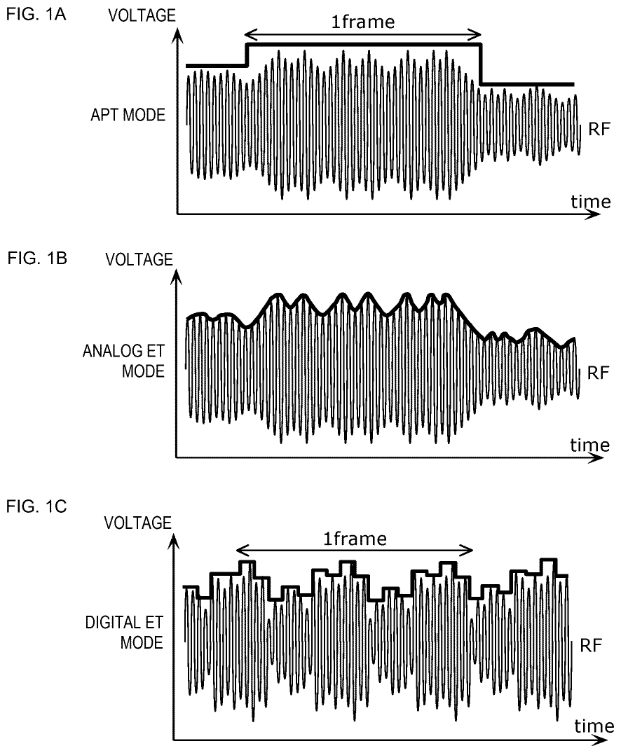

First, as a technology for highly efficiently amplifying an RF signal, a tracking mode in which a power supply voltage, which is dynamically adjusted over time based on the RF signal, is supplied to a power amplifier will be described. The tracking mode is a mode in which the power supply voltage applied to the power amplifier is dynamically adjusted. There are several types of tracking modes. Here, an average power tracking (APT) mode as well as ET (ET: Envelope Tracking) modes (including an analog ET mode and a digital ET mode) will be described with reference to FIGS. 1A to 1C. In FIGS. 1A to 1C, the horizontal axis represents time and the vertical axis represents voltage. Additionally, a thick solid line represents a power supply voltage, and a thin solid line (e.g., a waveform) represents a modulated signal.

FIG. 1A is a graph illustrating an example of the transition of the power supply voltage in the APT mode. In the APT mode, the power supply voltage is varied to multiple discrete voltage levels on a frame-by-frame basis based on the average power. As a result, the power supply voltage signal forms a rectangular wave.

In an exemplary aspect, a frame can refer to a unit forming an RF signal (e.g., a modulated signal). For example, in 5GNR (5th Generation New Radio) and LTE (Long Term Evolution), a frame includes ten subframes, each subframe includes multiple slots, and each slot consists of multiple symbols. The subframe length is 1 millisecond (ms), and the frame length is 10 ms.

Note that a mode in which the voltage level is varied based on the average power in units of one frame or larger is referred to as the APT mode, and is distinguished from a mode in which the voltage level is varied in units smaller than one frame (e.g., subframes, slots, or symbols).

FIG. 1B is a graph illustrating an example of the transition of the power supply voltage in the analog ET mode. In the analog ET mode, the envelope of a modulated signal is tracked by continuously varying the power supply voltage based on an envelope signal.

An envelope signal is a signal that represents the envelope of a modulated signal. An envelope value is represented, for example, by the square root of (I²+Q²), where (I, Q) represents a constellation point. A constellation point is a point on a constellation diagram that represents a signal modulated by digital modulation. (I, Q) is determined, for example, based on the transmitted information, for example, by a BBIC (Baseband Integrated Circuit).

FIG. 1C is a graph illustrating an example of the transition of the power supply voltage in the digital ET mode. In the digital ET mode, the envelope of a modulated signal is tracked by varying the power supply voltage to multiple discrete voltage levels within one frame based on the envelope signal. As a result, the power supply voltage signal forms a rectangular wave.

### (Exemplary Embodiment)

### [1. Circuit Configuration of RF Module 1 and Communication Device 4]

A communication device 4 according to the present embodiment corresponds to user equipment (UE) in a cellular network, and typically includes a mobile phone, smartphone, tablet computer, wearable device, or the like. Note that the communication device 4 may be an IoT (Internet of Things) sensor device, medical/healthcare device, vehicle, unmanned aerial vehicle (UAV) (so-called drone), or automated guided vehicle (AGV). Additionally, the communication device 4 can be configured as a BS (Base Station) in a cellular network.

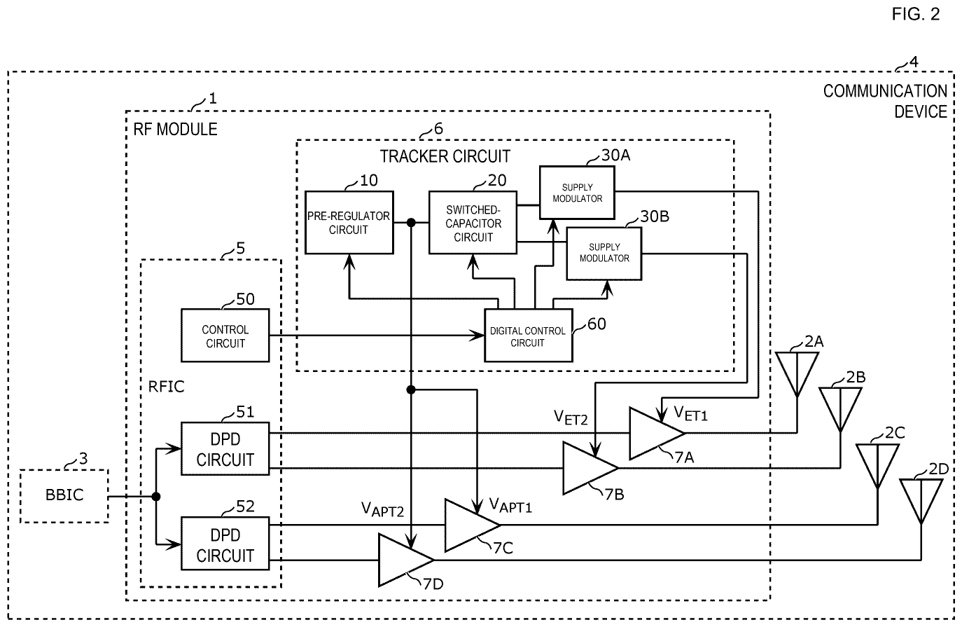

The circuit configuration of the communication device 4 and the RF module 1 according to the present embodiment will be described with reference to FIG. 2. FIG. 2 is a circuit configuration diagram of the RF module 1 and the communication device 4 according to the embodiment.

It is noted that FIG. 2 illustrates an exemplary circuit configuration, and the communication device 4 and the RF module 1 may be implemented using any of a wide variety of circuit implementations and circuit technologies. Therefore, the following descriptions of the communication device 4 and the RF module 1 should not be interpreted in a limiting sense.

The communication device 4 includes the RF module 1, antennas 2A, 2B, 2C, and 2D, and a BBIC 3. The RF module 1 includes an RFIC 5, a tracker circuit 6, and power amplifiers 7A, 7B, 7C, and 7D, and forms a power amplification system.

The power amplifier 7A is an example of a first power amplifier, connected to the antenna 2A (first antenna), and configured to amplify a wireless local area network signal in a first frequency band. More specifically, the power amplifier 7A has an input end connected to the RFIC 5, and a voltage input end connected to the tracker circuit 6. With the above connection configuration, the power amplifier 7A is able to amplify an RF signal in the first frequency band of the WLAN, which is output from the RFIC 5, with a power supply voltage V_{ET1} in the digital ET mode supplied from the tracker circuit 6. That is, the digital ET mode is applied to the power amplifier 7A.

The power amplifier 7B is an example of a second power amplifier, connected to the antenna 2B (second antenna), and configured to amplify a wireless local area network signal in the first frequency band. More specifically, the power amplifier 7B has an input end connected to the RFIC 5, and a voltage input end connected to the tracker circuit 6. With the above connection configuration, the power amplifier 7B is able to amplify an RF signal in the first frequency band of the WLAN, which is output from the RFIC 5, with a power supply voltage V_{ET2} in the digital ET mode supplied from the tracker circuit 6. That is, the digital ET mode is applied to the power amplifier 7B.

The first frequency band includes, for example, at least one of the 5 GHz band, the 6 GHz band, and the 7 GHZ band.

The power amplifier 7C is an example of a third power amplifier, connected to the antenna 2C, and configured to amplify a wireless local area network signal in a second frequency band lower than the first frequency band. More specifically, the power amplifier 7C has an input end connected to the RFIC 5, and a voltage input end connected to the tracker circuit 6. With the above connection configuration, the power amplifier 7C is able to amplify an RF signal in the second frequency band of the WLAN, which is output from the RFIC 5, with a power supply voltage V_{APT1} in the APT mode supplied from the tracker circuit 6. That is, the APT mode is applied to the power amplifier 7C.

The power amplifier 7D is an example of the third power amplifier, connected to the antenna 2D, and configured to amplify a wireless local area network signal in the second frequency band. More specifically, the power amplifier 7D has an input end connected to the RFIC 5, and a voltage input end connected to the tracker circuit 6. With the above connection configuration, the power amplifier 7D is able to amplify an RF signal in the second frequency band of the WLAN, which is output from the RFIC 5, with a power supply voltage V_{APT2} in the APT mode supplied from the tracker circuit 6. That is, the APT mode is applied to the power amplifier 7D.

The second frequency band includes, for example, the 2.4 GHz band.

The antennas 2A to 2D can transmit RF signals amplified by the power amplifiers 7A to 7D to the outside of the communication device 4. It is noted that some or all of the antennas 2A to 2D may not be included in the communication device 4 in an exemplary aspect.

The RFIC 5 is an example of a signal processing circuit that processes RF signals (WLAN signals). The RFIC 5 can receive a digital IQ signal from the BBIC 3 and supply WLAN signals to the power amplifiers 7A to 7D. Specifically, the RFIC 5 can supply a WLAN signal in the first frequency band to the power amplifiers 7A and 7B and can supply a WLAN signal in the second frequency band to the power amplifiers 7C and 7D.

The BBIC 3 is a baseband signal processing circuit that processes signals using a frequency band lower than RF signals. The BBIC 3 can, for example, generate a digital IQ signal by digitally modulating a bit sequence representing an image signal for image display and/or an audio signal for voice communication via a speaker. The generated digital IQ signal is supplied to the RFIC 5. Note that the BBIC 3 may be included in the RF module 1.

The tracker circuit 6 can supply the power supply voltage V_{ET1} to the power amplifier 7A in the digital ET mode, supply the power supply voltage V_{ET2} to the power amplifier 7B in the digital ET mode, supply the power supply voltage V_{APT1} to the power amplifier 7C in the APT mode, and supply the power supply voltage V_{APT2} to the power amplifier 7D in the APT mode.

Specifically, the tracker circuit 6 can generate multiple discrete voltages from an input voltage supplied from a DC power supply (not illustrated), and selectively supply at least one of the generated discrete voltages to the power amplifiers 7A and 7B. At that time, at least one of the discrete voltages is selected based on the envelope of the WLAN signal in the first frequency band. This configuration enables the tracker circuit 6 to dynamically vary the power supply voltages V_{ET1} and V_{ET2}, for example, in units smaller than one frame, based on the envelope of the WLAN signal in the first frequency band.

Furthermore, specifically, the tracker circuit 6 can generate a voltage from an input voltage supplied from a DC power supply (not illustrated) and supply the generated voltage to the power amplifiers 7C and 7D. At that time, the level of the generated voltage is determined based on the average power of the WLAN signal in the second frequency band. This configuration enables the tracker circuit 6 to dynamically vary the power supply voltages V_{APT1} and V_{APT2}, for example, in units of one or more frames, based on the average power of the WLAN signal in the second frequency band.

### [1.1. Circuit Configuration of RFIC 5]

Next, the specific circuit configuration of the RFIC 5 will be described. As illustrated in FIG. 2, the RFIC 5 includes a control circuit 50 and DPD (Digital Pre-Distortion) circuits 51 and 52.

The control circuit 50 is a circuit that is configured to control the tracker circuit 6, and specifically outputs a control signal to a digital control circuit 60 of the tracker circuit 6. It is noted that the control circuit 50 may not be included in the RFIC 5 in an exemplary aspect, and may instead be included in the BBIC 3, for example.

The DPD circuit 51 is an example of a first digital pre-distortion circuit and is configured to pre-distort a WLAN signal in the first frequency band. The DPD circuit 51 can pre-distort a digital IQ signal supplied from the BBIC 3, for example, using a mathematical model for DPD. For example, the DPD circuit 51 can generate a pre-distorted digital IQ signal from the digital IQ signal. The pre-distorted digital IQ signal is converted to an analog IQ signal at a DAC (not illustrated), then orthogonally modulated and up-converted at a quadrature modulator (not illustrated) to generate a WLAN signal in the first frequency band, which is output to the power amplifiers 7A and 7B.

The DPD circuit 52 is an example of a second digital pre-distortion circuit and is configured to pre-distort a WLAN signal in the second frequency band. The DPD circuit 52 can pre-distort a digital IQ signal supplied from the BBIC 3, for example, using a mathematical model for DPD. For example, the DPD circuit 52 can generate a pre-distorted digital IQ signal from the digital IQ signal. The pre-distorted digital IQ signal is converted to an analog IQ signal at a DAC (not illustrated), then orthogonally modulated and up-converted at a quadrature modulator (not illustrated) to generate a WLAN signal in the second frequency band, which is output to the power amplifiers 7C and 7D.

It is noted that each of the DPD circuits 51 and 52 may skip DPD processing. In this case, each of the DPD circuits 51 and 52 can supply a digital IQ signal (i.e., an undistorted digital IQ signal) supplied from the BBIC 3 to the power amplifiers 7A to 7D.

In the present embodiment, the DPD circuit 51 performs DPD processing on a digital IQ signal for a WLAN signal in the 5 to 7 GHz band, while the DPD circuit 52 performs DPD processing on a digital IQ signal for a WLAN signal in the 2.4 GHz band. In contrast, the DPD circuit 51 may pre-distort a WLAN signal in the 5-7 GHz band, while the DPD circuit 52 need not pre-distort a WLAN signal in the 2.4 GHz band.

It is noted that the circuit configuration of the RFIC 5 represented in FIG. 2 is exemplary, and the circuit configuration is not limited thereto. For example, one of the DPD circuits 51 and 52 may not be included in the RFIC 5 in an exemplary aspect. For example, the DPD circuit 52 may be arranged outside of the RFIC 5. Additionally, the DPD circuits 51 and 52 may be composed of one DPD circuit.

Here, as the mathematical model used in the DPD circuits 51 and 52, a first mathematical model incorporating memory effects or a second mathematical model without memory effects can be used.

Memory effects are defined as changes in power amplifier distortion caused by past input signals. Therefore, in the first mathematical model, not only the distortion caused by the current input signal, but also changes in distortion caused by the past input signals are modeled. Therefore, the first mathematical model can reduce nonlinear distortion more than the second mathematical model.

In the present embodiment, for example, the DPD circuit 51 may pre-distort a WLAN signal in the first frequency band using the first mathematical model, while the DPD circuit 52 may pre-distort a WLAN signal in the second frequency band using the second mathematical model.

### [1.2. Circuit Configuration of Tracker Circuit 6]

Next, the specific circuit configuration of the tracker circuit 6 will be described. As illustrated in FIG. 2, the tracker circuit 6 includes a pre-regulator circuit 10, a switched-capacitor circuit 20, supply modulators 30A and 30B, and the digital control circuit 60.

The pre-regulator circuit 10 can convert an input voltage supplied from a DC power supply (not illustrated) into a regulated voltage using a power inductor. The pre-regulator circuit 10 includes a power inductor and a switch. The power inductor is an inductor used to step up and/or step down a direct current (DC) voltage. The power inductor is arranged in series in a DC path. Note that the power inductor may be connected between the DC path and ground (i.e., arranged in parallel to the DC path). The pre-regulator circuit 10 as such may also be referred to as a magnetic regulator or a DC/DC converter. It is noted that the pre-regulator circuit 10 may not include a power inductor in an exemplary aspect.

The switched-capacitor circuit 20 includes multiple capacitors and multiple switches and is configured to generate multiple discrete voltages respectively having discrete voltage levels from a voltage supplied from the pre-regulator circuit 10. The switched-capacitor circuit 20 may also be referred to as a switched-capacitor voltage ladder in an exemplary aspect.

The pre-regulator circuit 10 and the switched-capacitor circuit 20 are included in a voltage generation circuit configured to generate multiple discrete voltages.

The supply modulator 30A is an example of a first supply modulator and is configured to select at least one of the discrete voltages generated by the switched-capacitor circuit 20 and output it the power amplifier 7A. The supply modulator 30B is an example of a second supply modulator and is configured to select at least one of the discrete voltages generated by the switched-capacitor circuit 20 and output it the power amplifier 7B.

The digital control circuit 60 is configured to control the pre-regulator circuit 10, switched-capacitor circuit 20, and supply modulators 30A and 30B based on a digital control signal from the control circuit 50.

It is noted that the tracker circuit 6 may not include some of the pre-regulator circuit 10, switched-capacitor circuit 20, supply modulators 30A and 30B, and digital control circuit 60 in an exemplary aspect. For example, the tracker circuit 6 may omit the pre-regulator circuit 10 in an exemplary aspect. Additionally, any combination of the pre-regulator circuit 10, switched-capacitor circuit 20, and supply modulators 30A and 30B may be integrated into a single circuit. Furthermore, the tracker circuit 6 may include, instead of the pre-regulator circuit 10 and the switched-capacitor circuit 20, a voltage supply circuit with another circuit configuration. The tracker circuit 6 may also include a filter circuit that attenuates noise from the discrete voltages, which is connected between the supply modulator 30A and the power amplifier 7A. Additionally, the tracker circuit 6 may include a filter circuit that attenuates noise from the discrete voltages, which is connected between the supply modulator 30B and the power amplifier 7B.

With the above configuration, the tracker circuit 6 can be configured to supply the power supply voltage V_{ET1} from the supply modulator 30A to the power amplifier 7A and supply the power supply voltage V_{ET2} from the supply modulator 30B to the power amplifier 7B. Additionally, the tracker circuit 6 can supply the power supply voltage V_{APT1} from the pre-regulator circuit 10 to the power amplifier 7C without passing through the supply modulators 30A and 30B. Furthermore, the tracker circuit 6 can supply the power supply voltage V_{APT2} from the pre-regulator circuit 10 to the power amplifier 7D without passing through the supply modulators 30A and 30B.

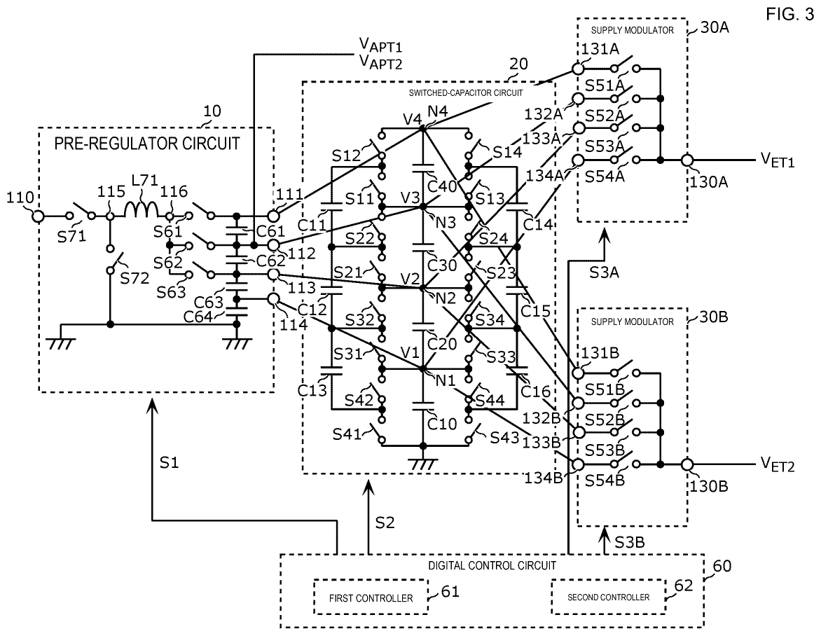

Next, the circuit configuration of each circuit included in the tracker circuit 6 will be described with reference to FIG. 3.

### [1.2.1. Circuit Configuration of Switched-Capacitor Circuit 20]

First, the circuit configuration of the switched-capacitor circuit 20 will be described. The switched-capacitor circuit 20 includes capacitors C11 to C16, capacitors C10, C20, C30, and C40, and switches S11 to S14, S21 to S24, S31 to S34, and S41 to S44. Energy and charge are input from the pre-regulator circuit 10 to the switched-capacitor circuit 20 at nodes N1 to N4 and are extracted from the switched-capacitor circuit 20 to the supply modulators 30A and 30B at the nodes N1 to N4.

Each of the capacitors C11 to C16 can be configured to function as a flying capacitor (sometimes referred to as a transfer capacitor). That is, each of the capacitors C11 to C16 is used to step up or step down the regulated voltage supplied from the pre-regulator circuit 10. More specifically, the capacitors C11 to C16 transfer charge between the capacitors C11 to C16 and the nodes N1 to N4 such that voltages V1 to V4 (voltages relative to ground potential) satisfying V1:V2:V3:V4=1:2:3:4 are maintained at the four nodes N1 to N4. The voltages V1 to V4 correspond to multiple discrete voltages respectively having discrete voltage levels.

The capacitor C11 has two electrodes. One of the two electrodes of the capacitor C11 is connected to one end of the switch S11 and one end of the switch S12. The other of the two electrodes of the capacitor C11 is connected to one end of the switch S21 and one end of the switch S22.

The capacitor C12 has two electrodes. One of the two electrodes of the capacitor C12 is connected to one end of the switch S21 and one end of the switch S22. The other of the two electrodes of the capacitor C12 is connected to one end of the switch S31 and one end of the switch S32.

The capacitor C13 has two electrodes. One of the two electrodes of the capacitor C13 is connected to one end of the switch S31 and one end of the switch S32. The other of the two electrodes of the capacitor C13 is connected to one end of the switch S41 and one end of the switch S42.

The capacitor C14 has two electrodes. One of the two electrodes of the capacitor C14 is connected to one end of the switch S13 and one end of the switch S14. The other of the two electrodes of the capacitor C14 is connected to one end of the switch S23 and one end of the switch S24.

The capacitor C15 has two electrodes. One of the two electrodes of the capacitor C15 is connected to one end of the switch S23 and one end of the switch S24. The other of the two electrodes of the capacitor C15 is connected to one end of the switch S33 and one end of the switch S34.

The capacitor C16 has two electrodes. One of the two electrodes of the capacitor C16 is connected to one end of the switch S33 and one end of the switch S34. The other of the two electrodes of the capacitor C16 is connected to one end of the switch S43 and one end of the switch S44.

Each set of the capacitors C11 and C14, the capacitors C12 and C15, and the capacitors C13 and C16 can perform complementary charging and discharging through repeated first and second phases.

Specifically, in the first phase, the switches S12, S13, S22, S23, S32, S33, S42 and S43 are switched on. As a result, for example, one of the two electrodes of the capacitor C12 is connected to the node N3, the other of the two electrodes of the capacitor C12 and one of the two electrodes of the capacitor C15 are connected to the node N2, and the other of the two electrodes of the capacitor C15 is connected to the node N1.

In contrast, in the second phase, the switches S11, S14, S21, S24, S31, S34, S41 and S44 are switched on. As a result, for example, one of the two electrodes of the capacitor C15 is connected to the node N3, the other of the two electrodes of the capacitor C15 and one of the two electrodes of the capacitor C12 are connected to the node N2, and the other of the two electrodes of the capacitor C12 is connected to the node N1.

Through the repetition of such first and second phases, one of the capacitors C12 and C15 can be charged from the node N2 while the other of the capacitors C12 and C15 discharges to the capacitor C30. In other words, the capacitors C12 and C15 can perform complementary charging and discharging.

Each set of the capacitors C11 and C14 and the capacitors C13 and C16 can perform complementary charging and discharging through repeated first and second phases, similar to the set of the capacitors C12 and C15.

Each of the capacitors C10, C20, C30, and C40 can be configured to function as a smoothing capacitor. That is, each of the capacitors C10, C20, C30, and C40 is used for holding and smoothing the voltages V1 to V4 at the nodes N1 to N4.

The capacitor C10 is connected between the node N1 and ground. Specifically, one of two electrodes of the capacitor C10 is connected to the node N1. In contrast, the other of the two electrodes of the capacitor C10 is connected to ground.

The capacitor C20 is connected between the node N2 and the node N1. Specifically, one of two electrodes of the capacitor C20 is connected to the node N2. In contrast, the other of the two electrodes of the capacitor C20 is connected to the node N1.

The capacitor C30 is connected between the node N3 and the node N2. Specifically, one of two electrodes of the capacitor C30 is connected to the node N3. In contrast, the other of the two electrodes of the capacitor C30 is connected to the node N2.

The capacitor C40 is connected between the node N4 and the node N3. Specifically, one of two electrodes of the capacitor C40 is connected to the node N4. In contrast, the other of the two electrodes of the capacitor C40 is connected to the node N3.

The switch S11 is connected between one of the two electrodes of the capacitor C11 and the node N3. Specifically, one end of the switch S11 is connected to one of the two electrodes of the capacitor C11. In contrast, the other end of the switch S11 is connected to the node N3.

The switch S12 is connected between one of the two electrodes of the capacitor C11 and the node N4. Specifically, one end of the switch S12 is connected to one of the two electrodes of the capacitor C11. In contrast, the other end of the switch S12 is connected to the node N4.

The switch S21 is connected between one of the two electrodes of the capacitor C12 and the node N2. Specifically, one end of the switch S21 is connected to one of the two electrodes of the capacitor C12 and the other of the two electrodes of the capacitor C11. In contrast, the other end of the switch S21 is connected to the node N2.

The switch S22 is connected between one of the two electrodes of the capacitor C12 and the node N3. Specifically, one end of the switch S22 is connected to one of the two electrodes of the capacitor C12 and the other of the two electrodes of the capacitor C11. In contrast, the other end of the switch S22 is connected to the node N3.

The switch S31 is connected between one of the two electrodes of the capacitor C12 and the node N1. Specifically, one end of the switch S31 is connected to the other of the two electrodes of the capacitor C12 and one of the two electrodes of the capacitor C13. In contrast, the other end of the switch S31 is connected to the node N1.

The switch S32 is connected between the other of the two electrodes of the capacitor C12 and the node N2. Specifically, one end of the switch S32 is connected to the other of the two electrodes of the capacitor C12 and one of the two electrodes of the capacitor C13. In contrast, the other end of the switch S32 is connected to the node N2. That is, the other end of the switch S32 is connected to the other end of the switch S21.

The switch S41 is connected between the other of the two electrodes of the capacitor C13 and ground. Specifically, one end of the switch S41 is connected to the other of the two electrodes of the capacitor C13. In contrast, the other end of the switch S41 is connected to ground.

The switch S42 is connected between the other of the two electrodes of the capacitor C13 and the node N1. Specifically, one end of the switch S42 is connected to the other of the two electrodes of the capacitor C13. In contrast, the other end of the switch S42 is connected to the node N1. That is, the other end of the switch S42 is connected to the other end of the switch S31.

The switch S13 is connected between one of the two electrodes of the capacitor C14 and the node N3. Specifically, one end of the switch S13 is connected to one of the two electrodes of the capacitor C14. In contrast, the other end of the switch S13 is connected to the node N3. That is, the other end of the switch S13 is connected to the other end of the switch S11 and the other end of the switch S22.

The switch S14 is connected between one of the two electrodes of the capacitor C14 and the node N4. Specifically, one end of the switch S14 is connected to one of the two electrodes of the capacitor C14. In contrast, the other end of the switch S14 is connected to the node N4. That is, the other end of the switch S14 is connected to the other end of the switch S12.

The switch S23 is connected between one of the two electrodes of the capacitor C15 and the node N2. Specifically, one end of the switch S23 is connected to one of the two electrodes of the capacitor C15 and the other of the two electrodes of the capacitor C14. In contrast, the other end of the switch S23 is connected to the node N2. That is, the other end of the switch S23 is connected to the other end of the switch S21 and the other end of the switch S32.

The switch S24 is connected between one of the two electrodes of the capacitor C15 and the node N3. Specifically, one end of the switch S24 is connected to one of the two electrodes of the capacitor C15 and the other of the two electrodes of the capacitor C14. In contrast, the other end of the switch S24 is connected to the node N3. That is, the other end of the switch S24 is connected to the other end of the switch S11, the other end of the switch S22, and the other end of the switch S13.

The switch S33 is connected between one of the two electrodes of the capacitor C15 and the node N1. Specifically, one end of the switch S33 is connected to the other of the two electrodes of the capacitor C15 and one of the two electrodes of the capacitor C16. In contrast, the other end of the switch S33 is connected to the node N1. That is, the other end of the switch S33 is connected to the other end of the switch S31 and the other end of the switch S42.

The switch S34 is connected between the other of the two electrodes of the capacitor C15 and the node N2. Specifically, one end of the switch S34 is connected to the other of the two electrodes of the capacitor C15 and one of the two electrodes of the capacitor C16. In contrast, the other end of the switch S34 is connected to the node N2. That is, the other end of the switch S34 is connected to the other end of the switch S21, the other end of the switch S32, and the other end of the switch S23.

The switch S43 is connected between the other of the two electrodes of the capacitor C16 and ground. Specifically, one end of the switch S43 is connected to the other of the two electrodes of the capacitor C16. In contrast, the other end of the switch S43 is connected to ground.

The switch S44 is connected between the other of the two electrodes of the capacitor C16 and the node N1. Specifically, one end of the switch S44 is connected to the other of the two electrodes of the capacitor C16. In contrast, the other end of the switch S44 is connected to the node N1. That is, the other end of the switch S44 is connected to the other end of the switch S31, the other end of the switch S42, and the other end of the switch S33.

A first set of switches including the switches S12, S13, S22, S23, S32, S33, S42 and S43 and a second set of switches including the switches S11, S14, S21, S24, S31, S34, S41 and S44 are complementarily switched on and off based on a control signal S2. Specifically, in the first phase, the first set of switches is switched on and the second set of switches is switched off. Conversely, in the second phase, the first set of switches is switched off and the second set of switches is switched on.

For example, in one of the first phase and the second phase, charging from the capacitors C11 to C13 to the capacitors C10 to C40 is performed, and in the other of the first phase and the second phase, charging from the capacitors C14 to C16 to the capacitors C10 to C40 is performed. That is, since the capacitors C10 to C40 are always charged from the capacitors C11 to C13 or the capacitors C14 to C16, even when current flows from the nodes N1 to N4 to the supply modulators 30A and 30B at high speed, charge is supplied to the nodes N1 to N4 at high speed, thereby suppressing potential fluctuations at the nodes N1 to N4.

Through such operations, the switched-capacitor circuit 20 can maintain approximately equal voltages at both ends of each of the capacitors C10, C20, C30, and C40. Specifically, at the four nodes labeled V1 to V4, the voltages V1 to V4 (voltages relative to ground potential) satisfying V1:V2:V3:V4=1:2:3:4 are maintained. The voltage levels of the voltages V1 to V4 correspond to multiple discrete voltage levels that can be supplied to the supply modulators 30A and 30B by the switched-capacitor circuit 20.

It is noted that the voltage ratio (V1:V2:V3:V4) is not limited to (1:2:3:4). For example, the voltage ratio (V1:V2:V3:V4) may be (1:2:4:8) in an alternative aspect.

Additionally, the configuration of the switched-capacitor circuit 20 illustrated in FIG. 3 is an example, and the configuration is not limited thereto. In FIG. 3, the switched-capacitor circuit 20 is configured to be able to supply four discrete voltages, but the number of discrete voltages is not limited thereto. The switched-capacitor circuit 20 may be configured to supply any number of two or more discrete voltages. For example, when supplying two discrete voltages, it is sufficient for the switched-capacitor circuit 20 to include at least the capacitors C12 and C15, and the switches S21 to S24 and S31 to S34.

### [1.2.2. Circuit Configuration of Supply Modulators 30A and 30B]

Next, the circuit configuration of the supply modulators 30A and 30B will be described. The supply modulator 30A includes input terminals 131A to 134A, switches S51A to S54A, and an output terminal 130A. The supply modulator 30B includes input terminals 131B to 134B, switches S51B to S54B, and an output terminal 130B.

The output terminal 130A is connected to the power amplifier 7A. The output terminal 130A is a terminal for supplying a power supply voltage selected from the voltages V1 to V4 to the power amplifier 7A.

The input terminals 131A to 134A are respectively connected to the nodes N4 to N1 of the switched-capacitor circuit 20. The input terminals 131A to 134A are terminals for receiving the voltages V4 to V1 from the switched-capacitor circuit 20.

The switch S51A is connected between the input terminal 131A and the output terminal 130A. Specifically, the switch S51A has a terminal connected to the input terminal 131A and a terminal connected to the output terminal 130A. In this connection configuration, the switch S51A is switched on/off by a control signal S3A, thereby enabling switching between connection and disconnection of the input terminal 131A and the output terminal 130A.

The switch S52A is connected between the input terminal 132A and the output terminal 130A. Specifically, the switch S52A has a terminal connected to the input terminal 132A and a terminal connected to the output terminal 130A. In this connection configuration, the switch S52A is switched on/off by the control signal S3A, thereby enabling switching between connection and disconnection of the input terminal 132A and the output terminal 130A.

The switch S53A is connected between the input terminal 133A and the output terminal 130A. Specifically, the switch S53A has a terminal connected to the input terminal 133A and a terminal connected to the output terminal 130A. In this connection configuration, the switch S53A is switched on/off by the control signal S3A, thereby enabling switching between connection and disconnection of the input terminal 133A and the output terminal 130A.

The switch S54A is connected between the input terminal 134A and the output terminal 130A. Specifically, the switch S54A has a terminal connected to the input terminal 134A and a terminal connected to the output terminal 130A. In this connection configuration, the switch S54A is switched on/off by the control signal S3A, thereby enabling switching between connection and disconnection of the input terminal 134A and the output terminal 130A.

These switches S51A to S54A are controlled to be switched on exclusively. That is, only one of the switches S51A to S54A is switched on, while the rest of the switches S51A to S54A are switched off. This configuration enables the supply modulator 30A to output one voltage selected from the voltages V1 to V4.

It is noted that the configuration of the supply modulator 30A illustrated in FIG. 3 is an example, and the configuration is not limited thereto. In particular, the switches S51A to S54A may have any configuration, as long as they are configured to selectively connect at least one of the four input terminals 131A to 134A to the output terminal 130A. For example, the supply modulator 30A may further include a switch connected between the switches S51A to S53A and the switch S54A, and the output terminal 130A. Additionally, for example, the supply modulator 30A may further include a switch connected between the switches S51A and S52A and the switches S53A and S54A and the output terminal 130A.

It is noted that when two discrete voltage levels are supplied from the switched-capacitor circuit 20, the supply modulator 30A only needs to include at least two of the switches S51A to S54A in an exemplary aspect.

It is also noted that because the configuration of the supply modulator 30B is a configuration in which the input terminals 131A to 134A of the supply modulator 30A are replaced with the input terminals 131B to 134B, and the switches S51A to S54A of the supply modulator 30A are replaced with the switches S51B to S54B, its description will be omitted. The output terminal 130B is connected to the power amplifier 7B. The output terminal 130B is a terminal for supplying a power supply voltage selected from the voltages V1 to V4 to the power amplifier 7B.

### [1.2.3. Circuit Configuration of Pre-Regulator Circuit 10]

Next, the circuit configuration of the pre-regulator circuit 10 will be described. The pre-regulator circuit 10 includes an input terminal 110, output terminals 111 to 114, switches S61 to S63, S71 and S72, a power inductor L71, and capacitors C61 to C64.

The input terminal 110 is a DC voltage input terminal. That is, the input terminal 110 is a terminal for receiving an input voltage from a DC power supply (not illustrated).

The output terminal 111 is a terminal for outputting the voltage V4. That is, the output terminal 111 is a terminal for supplying the voltage V4 to the switched-capacitor circuit 20. The output terminal 111 is connected to the node N4 of the switched-capacitor circuit 20.

The output terminal 112 is an output terminal for outputting the voltage V3. That is, the output terminal 112 is a terminal for supplying the voltage V3 to the switched-capacitor circuit 20. The output terminal 112 is connected to the node N3 of the switched-capacitor circuit 20. Additionally, the output terminal 112 is a terminal for supplying the voltage V3 (supply voltage V_{APT1}), derived from an input voltage supplied from a DC power supply (not illustrated), to the power amplifier 7C, and for supplying the voltage V3 (supply voltage V_{APT2}), derived from an input voltage supplied from a DC power supply (not illustrated), to the power amplifier 7D.

The output terminal 113 is a terminal for supplying the voltage V2. That is, the output terminal 113 is a terminal for supplying the voltage V2 to the switched-capacitor circuit 20. The output terminal 113 is connected to the node N2 of the switched-capacitor circuit 20.

The output terminal 114 is an output terminal for outputting the voltage V1. That is, the output terminal 114 is a terminal for supplying the voltage V1 to the switched-capacitor circuit 20. The output terminal 114 is connected to the node N1 of the switched-capacitor circuit 20.

It is noted that the power supply voltages V_{APT1} and V_{APT2} need not be supplied from the output terminal 112, and instead may be supplied from any of the output terminals 111 to 114. Additionally, the power supply voltages V_{APT1} and V_{APT2} need not be supplied from the same output terminal 112, and instead may be supplied from different output terminals.

The switch S71 is connected between the input terminal 110 and one end of the power inductor L71. Specifically, the switch S71 has a terminal connected to the input terminal 110 and a terminal connected to one end of the power inductor L71. In this connection configuration, the switch S71 is switched on and off based on a control signal S1, thereby enabling switching between connection and disconnection of the input terminal 110 and one end of the power inductor L71.

The switch S72 is connected between one end of the power inductor L71 and ground. Specifically, the switch S72 has a terminal connected to one end of the power inductor L71 and a terminal connected to ground. In this connection configuration, the switch S72 is switched on and off based on the control signal S1, thereby enabling switching between connection and disconnection of one end of the power inductor L71 and ground.

The switch S61 is connected between the other end of the power inductor L71 and the output terminal 111. Specifically, the switch S61 has a terminal connected to the other end of the power inductor L71 and a terminal connected to the output terminal 111. In this connection configuration, the switch S61 is switched on and off based on the control signal S1, thereby enabling switching between connection and disconnection of the other end of the power inductor L71 and the output terminal 111.

The switch S62 is connected between the other end of the power inductor L71 and the output terminal 112. Specifically, the switch S62 has a terminal connected to the other end of the power inductor L71 and a terminal connected to the output terminal 112. In this connection configuration, the switch S62 is switched on and off based on the control signal S1, thereby enabling switching between connection and disconnection of the other end of the power inductor L71 and the output terminal 112.

The switch S63 is connected between the other end of the power inductor L71 and the output terminal 113. Specifically, the switch S63 has a terminal connected to the other end of the power inductor L71 and a terminal connected to the output terminal 113. In this connection configuration, the switch S63 is switched on and off based on the control signal S1, thereby enabling switching between connection and disconnection of the other end of the power inductor L71 and the output terminal 113.

One of the two electrodes of the capacitor C61 is connected to the switch S61 and the output terminal 111. The other of the two electrodes of the capacitor C61 is connected to the switch S62, the output terminal 112, and one of the two electrodes of the capacitor C62.

One of the two electrodes of the capacitor C62 is connected to the switch S62, the output terminal 112, and the other of the two electrodes of the capacitor C61. The other of the two electrodes of capacitor C62 is connected to a path that connects the switch S63, the output terminal 113, and one of the two electrodes of capacitor C63.

One of the two electrodes of the capacitor C63 is connected to the switch S63, the output terminal 113, and the other of the two electrodes of the capacitor C62. The other of the two electrodes of the capacitor C63 is connected to the output terminal 114 and one of the two electrodes of the capacitor C64.

One of the two electrodes of the capacitor C64 is connected to the output terminal 114 and the other of the two electrodes of the capacitor C63. The other of the two electrodes of the capacitor C64 is connected to ground.

The switches S61 to S63 are controlled to be switched on exclusively. That is, only one of the switches S61 to S63 is switched on, while the rest of the switches S61 to S63 are switched off. By switching on only one of the switches S61 to S63, the pre-regulator circuit 10 can vary the voltage supplied to the switched-capacitor circuit 20 among the voltage levels V2 to V4. Additionally, by switching on the switch S62, the pre-regulator circuit 10 can generate the voltage V3 (supply voltages V_{APT1} and V_{APT2}) to be supplied to the power amplifiers 7C and 7D.

The pre-regulator circuit 10 configured as described above can supply charge to the switched-capacitor circuit 20 and the power amplifiers 7C and 7D via at least one of the output terminals 111 to 114.

It is noted that when the input voltage only needs to be converted to a single regulated voltage, the pre-regulator circuit 10 only needs to include at least the switches S71 and S72 and the power inductor L71.

### [1.2.4. Circuit Configuration of Digital Control Circuit 60]

Next, the circuit configuration of the digital control circuit 60 will be described. The digital control circuit 60 includes a first controller 61 and a second controller 62.

The first controller 61 can process a serial data signal (DATA) based on a clock signal (CLK) supplied from the RFIC 5 to generate the control signals S1 and S2. Here, a serial data signal refers to a data signal transmitted one bit at a time over a single signal line or circuit.

The control signal S1 is a signal for controlling the switching on and off of the switches S61 to S63, S71, and S72 included in the pre-regulator circuit 10. The control signal S2 is a signal for controlling the switching on and off of the switches S11 to S14, S21 to S24, S31 to S34 and S41 to S44 included in the switched-capacitor circuit 20.

For the clock signal for processing the serial data signal by the first controller 61, a separate signal line different from one for the serial data signal is used, but the configuration is not limited thereto. For example, the clock signal may be transmitted on the same signal line as the serial data signal.

Additionally, although one serial data signal is used for controlling the pre-regulator circuit 10 and the switched-capacitor circuit 20 in the present embodiment, multiple serial data signals may be used.

The second controller 62 can process digital control logic (DCL: Digital Control Logic/Line) signals (DCL1, DCL2) supplied from the RFIC 5 to generate control signals S3A and S3B. The DCL signals are an example of parallel data signals. Here, parallel data signals refer to data signals transmitted in parallel simultaneously over multiple signal lines or circuits.

The DCL signals (DCL1, DCL2) are generated by the RFIC 5 based on the envelope signal of an RF signal when the digital ET mode is applied to the power amplifiers 7A and 7B. Therefore, the control signals S3A and S3B are signals for controlling the switching on and off of the switches S51A to S54A included in the supply modulator 30A and the switches S51B to S54B included in the supply modulator 30B, when the digital ET mode is applied to the power amplifiers 7A and 7B.

Each of the DCL signals (DCL1, DCL2) is a 1-bit signal according to the exemplary aspect. Moreover, each of the voltages V1 to V4 is represented by a combination of two 1-bit signals. For example, V1, V2, V3, and V4 are respectively represented by “00”, “01”, “10”, and “11”. Gray code may be used to represent the voltage levels.

Although two DCL signals are used to control the supply modulators 30A and 30B in the digital ET mode in the present embodiment, the number of DCL signals is not limited to this. Additionally, the digital control signals used to control the supply modulators 30A and 30B are not limited to DCL signals.

### [2. Implementation Configuration of RF Module 1]

Next, the implementation configuration of the RF module 1 according to the present embodiment will be described.

### [2.1. Implementation Configuration of Tracker Circuit 6]

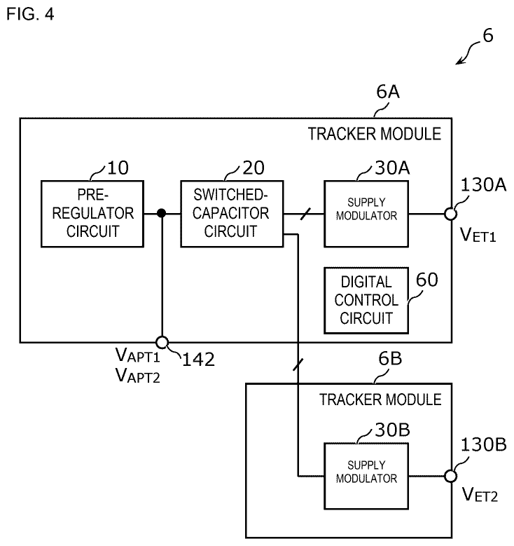

FIG. 4 is a module configuration diagram of the tracker circuit 6 according to the embodiment. As illustrated in the diagram, the tracker circuit 6 is configured with tracker modules 6A and 6B.

The tracker module 6A is an example of a first tracker module, and includes the pre-regulator circuit 10, the switched-capacitor circuit 20, the supply modulator 30A, and the digital control circuit 60. The tracker module 6B is an example of a second tracker module and includes the supply modulator 30B.

In the tracker module 6A, the circuit components forming the pre-regulator circuit 10, switched-capacitor circuit 20, and supply modulator 30A are (1) arranged on or in a single module substrate or (2) housed within a single package. Additionally, in the tracker module 6B, the circuit components forming the supply modulator 30B are (1) arranged on or in a single module substrate or (2) housed within a single package. It is noted that the supply modulator 30B may not be included in the tracker module 6B in an exemplary aspect, and instead each of the circuit components forming the supply modulator 30B may be directly arranged on a mother board (e.g., a module substrate 200 described later).

The power supply voltage V_{ET1} is supplied to the power amplifier 7A via the output terminal 130A, which is an external connection terminal of the tracker module 6A. The power supply voltage V_{ET2} is supplied to the power amplifier 7B via the output terminal 130B, which is an external connection terminal of the tracker module 6B. The power supply voltages V_{APT1} and V_{APT2}are supplied to the power amplifiers 7C and 7D via an output terminal 142, which is an external connection terminal of the tracker module 6A. Note that the power supply voltages V_{APT1} and V_{APT2} may be respectively supplied to the power amplifiers 7C and 7D via two different external connection terminals of the tracker module 6A.

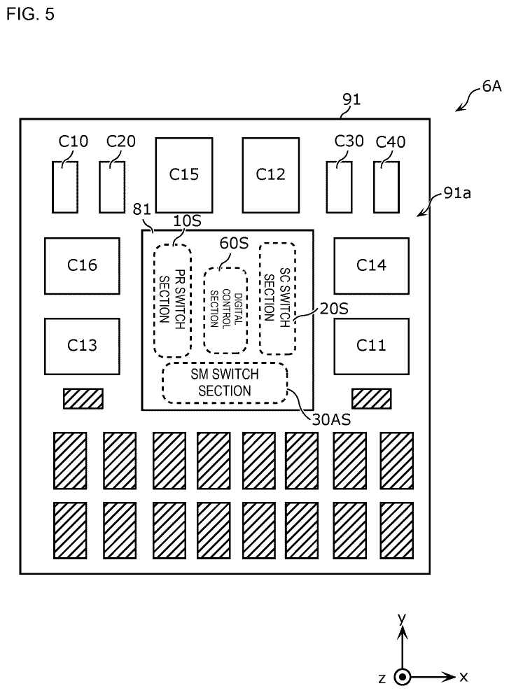

FIG. 5 is a plan view of the tracker module 6A according to the embodiment. It is noted that, in FIG. 5, wiring connecting the multiple circuit components arranged on or in a module substrate 91 is omitted. Additionally, in FIG. 5, illustrations of a resin member and a shield electrode layer arranged on a main surface 91a of the module substrate 91 are omitted. It is also noted that the resin member and the shield electrode layer may be omitted in an exemplary aspect. Furthermore, the hatched blocks in FIG. 5 represent optional circuit components in an exemplary aspect.

As shown, the tracker module 6A includes the module substrate 91 and an integrated circuit 81, as illustrated in FIG. 5.

The module substrate 91 is an example of a second module substrate and has the main surface 91a. A ground electrode layer and the like are formed within the module substrate 91 and on the main surface 91a. Note that, in FIG. 5, the module substrate 91 has a rectangular shape in plan view; however, the shape of the module substrate 91 is not limited thereto.

As the module substrate 91, for example, a low temperature co-fired ceramics (LTCC) substrate or a high temperature co-fired ceramics (HTCC) substrate having a multilayer structure of dielectric layers, a component-embedded board, a substrate having a redistribution layer (RDL), or a printed circuit board can be used; however, the module substrate 91 is not limited to these substrates.

The integrated circuit 81 is an example of a first integrated circuit and is one of the integrated circuits forming the tracker circuit 6. The integrated circuit 81 is arranged on or in the main surface 91a of the module substrate 91, and includes a PR switch section 10S, an SC switch section 20S, an SM switch section 30AS, and a digital control section 60S. The PR switch section 10S includes the switches S61 to S63, S71, and S72 of the pre-regulator circuit 10. The SC switch section 20S includes the switches S11 to S14, S21 to S24, S31 to S34, and S41 to S44 of the switched-capacitor circuit 20. The SM switch section 30AS includes the switches S51A to S54A of the supply modulator 30A. The digital control section 60S includes the digital control circuit 60.

It is noted that the integrated circuit 81 only needs to include at least one switch included in the supply modulator 30A, and may omit the PR switch section 10S, the SC switch section 20S, or the digital control section 60S in exemplary aspects.

Additionally, in FIG. 5, the integrated circuit 81 has a rectangular shape in plan view of the module substrate 91; however, the shape of the integrated circuit 81 is not limited thereto.

The integrated circuit 81 may be configured using, for example, CMOS (Complementary Metal Oxide Semiconductor), and specifically, it may be manufactured by an SOI (Silicon on Insulator) process. Note that the integrated circuit 81 is not limited to CMOS.

It is noted that the tracker module 6A further includes the capacitors C61 to C64 (not illustrated) and the power inductor L71 (not illustrated) included in the pre-regulator circuit 10, as well as the capacitors C11 to C16 and the capacitors C10 to C40 included in the switched-capacitor circuit 20.

The capacitors C61 to C64, the power inductor L71, the capacitors C11 to C16, and the capacitors C10 to C40 are arranged on or in the main surface 91a. Note that the power inductor L71 may be arranged outside the tracker module 6A.

According to an exemplary aspects, each of the capacitors C61 to C64, the capacitors C11 to C16, and the capacitors C10 to C40 can be implemented as a chip capacitor, which may refer to a surface mount device (SMD) forming a capacitor. It is noted that the implementation of multiple capacitors is not limited to chip capacitors. For example, some or all of the multiple capacitors may be included in an integrated passive device (IPD) or may be included in the integrated circuit 81.

At least one of the integrated circuit 81, the capacitors C61 to C64, the power inductor L71, the capacitors C11 to C16, and the capacitors C10 to C40 may be arranged inside the module substrate 91 or on or in the main surface facing the main surface 91a.

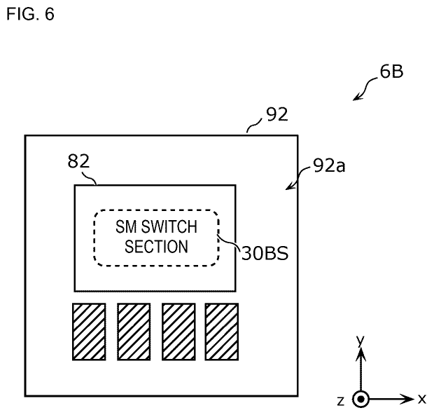

FIG. 6 is a plan view of the tracker module 6B according to the embodiment. Note that, in FIG. 6, wiring connecting the multiple circuit components arranged on or in a module substrate 92 is omitted. Additionally, in FIG. 6, illustrations of a resin member and a shield electrode layer arranged on a main surface 92a of the module substrate 92 are omitted. Note that the resin member and the shield electrode layer may be omitted. Furthermore, it is noted that the hatched blocks in FIG. 6 represent optional circuit components in an exemplary aspect.

As shown, the tracker module 6B includes the module substrate 92 and an integrated circuit 82, as illustrated in FIG. 6.

The integrated circuit 82 is an example of a second integrated circuit and is one of the integrated circuits forming the tracker circuit 6. The integrated circuit 82 is arranged on or in the main surface 92a of the module substrate 92 and includes an SM switch section 30BS. The SM switch section 30BS includes the switches S51B to S54B of the supply modulator 30B. It is noted that the integrated circuit 82 may omit the PR switch section 10S, the SC switch section 20S, or the SM switch section 30AS in an exemplary aspect, and only needs to include at least one switch included in the supply modulator 30B. Additionally, the integrated circuit 82 is not arranged on or in the module substrate 91. In other words, the tracker module 6A and the tracker module 6B are separate units.

Note that, in FIG. 6, the integrated circuit 82 has a rectangular shape in plan view of the module substrate 92; however, the shape of the integrated circuit 82 is not limited thereto.

As the module substrate 92, for example, an LTCC substrate or an HTCC substrate having a multilayer structure of dielectric layers, a component-embedded board, a substrate having an RDL, or a printed circuit board can be used; however, the module substrate 92 is not limited to these substrates.

The integrated circuit 82 may be configured using CMOS, for example, and specifically, it may be manufactured by an SOI process. Note that the integrated circuit 82 is not limited to CMOS.

Note that the integrated circuit 82 may be arranged inside the module substrate 92 or on or in the main surface facing the main surface 92a.

### [2.2. Implementation Configuration of RF Module 1]

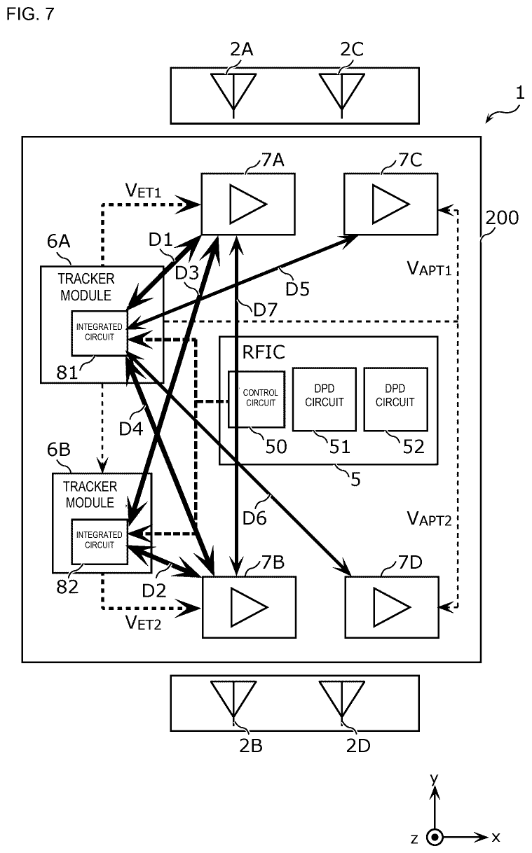

FIG. 7 is a plan view of the RF module 1 according to the embodiment. Note that, in FIG. 7, a portion of wiring connecting the multiple circuit components arranged on or in the module substrate 200 is omitted. Additionally, in FIG. 7, illustrations of a resin member and a shield electrode layer arranged on the main surface of the module substrate 200 are omitted. Note that the resin member and the shield electrode layer may be omitted.

The RF module 1 includes the module substrate 200, the RFIC 5, the power amplifiers 7A to 7D, and the tracker modules 6A and 6B, as illustrated in FIG. 7.

The module substrate 200 is an example of a first module substrate, and the power amplifiers 7A to 7D, the tracker modules 6A and 6B, and the RFIC 5 are arranged on or in the module substrate 200. The module substrate 200 is a mother board different from the module substrates 91 and 92. A ground electrode layer and the like are formed inside the module substrate 200 and on its main surface. Note that, in FIG. 7, the module substrate 200 has a rectangular shape in plan view; however, the shape of the module substrate 200 is not limited thereto.

As the module substrate 200, for example, an LTCC substrate or an HTCC substrate having a multilayer structure of dielectric layers, a component-embedded board, a substrate having an RDL, or a printed circuit board can be used; however, the module substrate 200 is not limited to these substrates.

As illustrated in FIG. 7, the antennas 2A and 2C are arranged above the module substrate 200 (in the positive y-axis direction), and the antennas 2B and 2D are arranged below the module substrate 200 (in the negative y-axis direction).

Correspondingly, the power amplifiers 7A and 7C are arranged in an upper region (a region in the positive y-axis direction) of the module substrate 200, and the power amplifiers 7B and 7D are arranged in a lower region (a region in the negative y-axis direction) of the module substrate 200. Additionally, the RFIC 5 is arranged between the power amplifiers 7A and 7C and the power amplifiers 7B and 7D.

According to the above configuration, the following transmission paths for WLAN signals can be shortened: (1) a transmission path for a WLAN signal connecting the RFIC 5, the power amplifier 7A, and the antenna 2A; (2) a transmission path for a WLAN signal connecting the RFIC 5, the power amplifier 7B, and the antenna 2B; (3) a transmission path for a WLAN signal connecting the RFIC 5, the power amplifier 7C, and the antenna 2C; and (4) a transmission path for a WLAN signal connecting the RFIC 5, the power amplifier 7D, and the antenna 2D. Accordingly, signal transmission losses can be reduced.

It is also noted that at least one of the antennas 2A to 2D may be arranged on or in the module substrate 200.

Here, as illustrated in FIG. 7, a distance D1 between the power amplifier 7A and the integrated circuit 81 is shorter than a distance D3 between the power amplifier 7A and the integrated circuit 82, and a distance D2 between the power amplifier 7B and the integrated circuit 82 is shorter than a distance D4 between the power amplifier 7B and the integrated circuit 81.

According to the above configuration, the integrated circuit 81, which is for supplying the power supply voltage V_{ET1} to the power amplifier 7A, can be arrange close to the power amplifier 7A, and the integrated circuit 82, which is for supplying the power supply voltage V_{ET2} to the power amplifier 7B, can be arrange close to the power amplifier 7B, as compared to the case where the integrated circuits 81 and 82 are integrated into a single integrated circuit. Therefore, the wiring connecting the integrated circuit 81 and the power amplifier 7A, and the wiring connecting the integrated circuit 82 and the power amplifier 7B, can be shortened, thereby suppressing efficiency degradation of the tracker circuit 6 in the digital ET mode while restraining an increase in power consumption.

Additionally, as illustrated in FIG. 7, the distance D1 between the power amplifier 7A and the integrated circuit 81 is shorter than one-half of a distance D7 between the power amplifier 7A and the power amplifier 7B, and the distance D2 between the power amplifier 7B and the integrated circuit 82 is shorter than one-half of the distance D7 between the power amplifier 7A and the power amplifier 7B.

According to an exemplary aspect, when the integrated circuits 81 and 82 are integrated into a single integrated circuit, in order to shorten the wiring connecting the integrated circuit 81 and the power amplifier 7A, and the wiring connecting the integrated circuit 82 and the power amplifier 7B in a balanced way, the aforementioned single integrated circuit is arranged near the midpoint between the power amplifiers 7A and 7B (hereinafter referred to as the “midpoint arrangement configuration”). In contrast, with the above arrangement configuration, the wiring connecting the integrated circuit 81 and the power amplifier 7A, and the wiring connecting the integrated circuit 82 and the power amplifier 7B, can be made even shorter than the case of the aforementioned midpoint arrangement configuration, thereby further suppressing efficiency degradation of the tracker circuit 6 and the RF module 1 in the digital ET mode while restraining an increase in power consumption.

In the exemplary aspect, power amplifier 7A and the integrated circuit 81 are also arranged adjacent to each other. This configuration enables the wiring connecting the integrated circuit 81 and the power amplifier 7A to be further shortened.

Similarly, it is desirable that the power amplifier 7B and the integrated circuit 82 be arranged adjacent to each other. This configuration enables the wiring connecting the integrated circuit 82 and the power amplifier 7B to be further shortened.

Furthermore, the distance D1 between the power amplifier 7A and the integrated circuit 81 is shorter than a distance D5 between the power amplifier 7C and the integrated circuit 81.

In the digital ET mode, the power supply voltage V_{ET1} fluctuates within one frame, whereas in the APT mode, the power supply voltage V_{APT1} fluctuates on a frame-by-frame basis. Accordingly, the power supply voltage V_{ET1} tends to have larger transmission losses than the power supply voltage V_{APT1}. In this regard, since the distance D1 is shorter than the distance D5, efficiency degradation of the tracker circuit 6 in the digital ET mode is further suppressed.

Similarly, the distance D2 between the power amplifier 7B and the integrated circuit 82 is shorter than a distance D6 between the power amplifier 7D and the integrated circuit 81. According to the above configuration, since the distance D2 is shorter than the distance D6, efficiency degradation of the tracker circuit 6 in the digital ET mode is further suppressed.

It is noted that, in the present embodiment, when the amplifier transistor and circuit components forming the power amplifier are directly arranged on the module substrate 200, the distance between the power amplifier and the integrated circuit that supplies the power supply voltage is defined as the shortest distance between the amplifier transistor included in the power amplifier and the outer surface of the integrated circuit supplying the power supply voltage.

Additionally, when the power amplifier is included in the integrated circuit, the distance between the power amplifier and the integrated circuit that supplies the power supply voltage is defined as the shortest distance between the outer surface of the integrated circuit including the power amplifier and the outer surface of the integrated circuit supplying the power supply voltage.

Additionally, when the amplifier transistor and circuit components forming the first power amplifier and the amplifier transistor and circuit components forming the second power amplifier are directly arranged on the module substrate 200, the distance between the first power amplifier and the second power amplifier is defined as the shortest distance between the amplifier transistor included in the first power amplifier and the amplifier transistor included in the second power amplifier.

Furthermore, when the first power amplifier is included in the integrated circuit and the second power amplifier is included in the integrated circuit, the distance between the first power amplifier and the second power amplifier is defined as the shortest distance between the outer surface of the integrated circuit including the first power amplifier and the outer surface of the integrated circuit including the second power amplifier.

### [3. Technical Effects]

As described above configuration, the RF module 1 according to the present embodiment includes: the power amplifier 7A connected to the antenna 2A and configured to amplify a WLAN signal in a first frequency band; the power amplifier 7B connected to the antenna 2B different from the antenna 2A and configured to amplify the WLAN signal in the first frequency band; a voltage generation circuit configured to generate multiple discrete voltages supplied to the power amplifiers 7A and 7B; the supply modulator 30A connected between the power amplifier 7A and the voltage generation circuit and configured to select at least one of the multiple discrete voltages and output it to the power amplifier 7A; the supply modulator 30B connected between the power amplifier 7B and the voltage generation circuit and configured to select at least one of the multiple discrete voltages and output it to the power amplifier 7B; the integrated circuit 81 including at least one switch included in the supply modulator 30A; and the integrated circuit 82 including at least one switch included in the supply modulator 30B, wherein the distance D1 between the power amplifier 7A and the integrated circuit 81 is shorter than the distance D3 between the power amplifier 7A and the integrated circuit 82, and the distance D2 between the power amplifier 7B and the integrated circuit 82 is shorter than the distance D4 between the power amplifier 7B and the integrated circuit 81.

According to the above configuration, the integrated circuit 81, which is for supplying the power supply voltage V_{ET1} to the power amplifier 7A, can be arranged close to the power amplifier 7A, and the integrated circuit 82, which is for supplying the power supply voltage V_{ET2} to the power amplifier 7B, can be arranged close to the power amplifier 7B, as compared to the case where the integrated circuits 81 and 82 are integrated into a single integrated circuit. Therefore, the wiring connecting the integrated circuit 81 and the power amplifier 7A, and the wiring connecting the integrated circuit 82 and the power amplifier 7B, can be shortened, thereby suppressing efficiency degradation of the tracker circuit 6 in the digital ET mode while restraining an increase in power consumption.

Additionally, the RF module 1 according to the present embodiment includes: the power amplifier 7A connected to the antenna 2A and configured to amplify a WLAN signal in a first frequency band; the power amplifier 7B connected to the antenna 2B different from the antenna 2A and configured to amplify the WLAN signal in the first frequency band; a voltage generation circuit configured to generate multiple discrete voltages supplied to the power amplifiers 7A and 7B; the supply modulator 30A connected between the power amplifier 7A and the voltage generation circuit and configured to select at least one of the multiple discrete voltages and output it to the power amplifier 7A; the supply modulator 30B connected between the power amplifier 7B and the voltage generation circuit and configured to select at least one of the multiple discrete voltages and output it to the power amplifier 7B; the integrated circuit 81 including at least one switch included in the supply modulator 30A; and the integrated circuit 82 including at least one switch included in the supply modulator 30B, wherein the distance D1 between the power amplifier 7A and the integrated circuit 81 is shorter than one-half of the distance D7 between the power amplifier 7A and the power amplifier 7B, and the distance D2 between the power amplifier 7B and the integrated circuit 82 is shorter than one-half of the distance D7 between the power amplifier 7A and the power amplifier 7B.

According to an exemplary aspect, when the integrated circuits 81 and 82 are integrated into a single integrated circuit, in order to shorten the wiring connecting the integrated circuit 81 and the power amplifier 7A, and the wiring connecting the integrated circuit 82 and the power amplifier 7B in a balanced way, the aforementioned single integrated circuit is arranged near the midpoint between the power amplifiers 7A and 7B (hereinafter referred to as the “midpoint arrangement configuration”). In contrast, with the above arrangement configuration, the wiring connecting the integrated circuit 81 and the power amplifier 7A, and the wiring connecting the integrated circuit 82 and the power amplifier 7B, can be made even shorter than the case of the aforementioned midpoint arrangement configuration, thereby further suppressing efficiency degradation of the tracker circuit 6 in the digital ET mode while restraining an increase in power consumption.

Additionally, for example, in the RF module 1, the power amplifier 7A and the integrated circuit 81 are arranged adjacent to each other, and the power amplifier 7B and the integrated circuit 82 are arranged adjacent to each other.

This configuration enables the wiring connecting the integrated circuit 81 and the power amplifier 7A, and the wiring connecting the integrated circuit 82 and the power amplifier 7B to be further shortened.

Furthermore, for example, the RF module 1 further includes the module substrate 200 on or in which the power amplifiers 7A and 7B, the voltage generation circuit, and the supply modulators 30A and 30B are arranged, and the voltage generation circuit and the integrated circuit 81 are arranged on or in the module substrate 91 different from the module substrate 200.

Accordingly, the RF module 1 can be miniaturized.

Additionally, for example, in the RF module 1, the integrated circuit 82 is not arranged on or in the module substrate 91.

This configuration enables the tracker module 6A including the integrated circuit 81 and the tracker module 6B including the integrated circuit 82 to be separate units.

Furthermore, for example, in the RF module 1, the first frequency band includes at least one of the 5 GHz band, the 6 GHz band, and the 7 GHz band.

According to the above configuration, since the WLAN signal in the higher frequency band among the two frequency bands of the WLAN can be driven using the digital ET, the efficiency of the tracker circuit 6 is improved.

Additionally, for example, the RF module 1 further includes the power amplifier 7C configured to amplify a WLAN signal in a second frequency band lower than the first frequency band, and the voltage generation circuit is configured to supply a voltage to the power amplifier 7C without passing through the supply modulators 30A and 30B.

According to the above configuration, since the WLAN signal in the lower frequency band among the two frequency bands of the WLAN can be driven using the APT, the efficiency of the tracker circuit 6 is improved.

Furthermore, for example, in the RF module 1, the second frequency band includes the 2.4 GHz band.

Additionally, for example, in the RF module 1, the integrated circuit 81 further includes at least one switch included in the voltage generation circuit, and the distance D1 between the power amplifier 7A and the integrated circuit 81 is shorter than the distance D5 between the power amplifier 7C and the integrated circuit 81.

In the digital ET mode, the power supply voltage V_{ET1} fluctuates within one frame, whereas in the APT mode, the power supply voltage V_{APT1} fluctuates on a frame-by-frame basis. Accordingly, the power supply voltage V_{ET1} has larger transmission losses than the power supply voltage V_{APT1}. In this regard, since the distance D1 is shorter than the distance D5, efficiency degradation of the tracker circuit 6 in the digital ET mode is further suppressed.

Additionally, for example, in the RF module 1, the distance D2 between the power amplifier 7B and the integrated circuit 82 is shorter than the distance D6 between the power amplifier 7D and the integrated circuit 81.

According to the above configuration, since the distance D2 is shorter than the distance D6, efficiency degradation of the tracker circuit 6 in the digital ET mode is further suppressed.

Furthermore, for example, the RF module 1 further includes the DPD circuit 51 configured to pre-distort the WLAN signal in the first frequency band.

According to the above configuration, nonlinear distortion of the WLAN signal amplified by the power amplifiers 7A and 7B can be reduced.

Additionally, for example, in the RF module 1, the DPD circuit 51 is arranged between the power amplifier 7A and the power amplifier 7B.

According to the above configuration, the wiring of the path for transmitting the WLAN signal is shortened, thereby reducing the signal transmission loss.

Additionally, for example, the RF module 1 further includes the DPD circuit 52 configured to pre-distort the WLAN signal in the second frequency band.

According to the above configuration, nonlinear distortion of the WLAN signal amplified by the power amplifiers 7C and 7D can be reduced.

### (Additional Exemplary Embodiments)

The RF module according to the exemplary aspects of the present disclosure has been described above with reference to the embodiment, but the exemplary RF module is not limited to the embodiment described above. Additional embodiments realized by combining arbitrary components in the above-described embodiment, various modifications obtained by applying various changes conceived by those skilled in the art to the above-described embodiment without departing from the spirit of the present invention, and various devices incorporating the above-described RF module are also included in the scope of the present disclosure.

For example, in the circuit configuration of various circuits according to the above-described embodiment, other circuit elements and wiring may be inserted between the circuit elements and signal paths disclosed in the drawings. For example, a filter may be inserted between a power amplifier and an antenna in an exemplary aspect.

Note that, although multiple discrete voltages are supplied from the switched-capacitor circuit to the supply modulators in the above-described embodiment, the exemplary aspects of the present disclosure is not limited thereto. For example, multiple discrete voltages may be supplied to the supply modulators from multiple DCDC converters. Note that, when the voltage levels of the multiple discrete voltages are evenly spaced, a switched-capacitor circuit can be used, as it is effective in miniaturizing the tracker module.

Furthermore, although the RF module 1 is not equipped with a reception path in the above-described embodiment, the RF module 1 may include a reception path.

According to the exemplary aspects of the present disclosure provided above, the exemplary embodiments can be widely applied to communication devices such as mobile phones, as an RF module for amplifying RF signals.

### REFERENCE SIGNS LIST

1 RF module
2A, 2B, 2C, 2D antennas
3 BBIC
4 communication device
5 RFIC
6 tracker circuit
6A, 6B tracker modules
7A, 7B, 7C, 7D power amplifiers
10 pre-regulator circuit
10S PR switch section
20 switched-capacitor circuit
20S SC switch section
30A, 30B supply modulators
30AS, 30BS SM switch sections
50 control circuit
51, 52 DPD circuits
60 digital control circuit
60S digital control section
61 first controller
62 second controller
81, 82 integrated circuits
91, 92, 200 module substrates
91a, 92a main surfaces
110, 131A, 131B, 132A, 132B, 133A, 133B, 134A, 134B input terminals
111, 112, 113, 114, 130A, 130B, 142 output terminals
D1, D2, D3, D4, D5, D6, D7 distances

1. A radio frequency module comprising:
a first power amplifier connected to a first antenna and configured to amplify a wireless local area network signal in a first frequency band;
a second power amplifier connected to a second antenna different from the first antenna and configured to amplify the wireless local area network signal in the first frequency band;
a voltage generation circuit configured to generate a plurality of discrete voltages;
a first supply modulator connected between the first power amplifier and the voltage generation circuit and configured to select and output at least one discrete voltage of the plurality of discrete voltages to the first power amplifier;
a second supply modulator connected between the second power amplifier and the voltage generation circuit and configured to select and output at least one discrete voltage of the plurality of discrete voltages to the second power amplifier;
a first integrated circuit including at least one switch included in the first supply modulator; and
a second integrated circuit including at least one switch included in the second supply modulator,
wherein a distance between the first power amplifier and the first integrated circuit is shorter than a distance between the first power amplifier and the second integrated circuit, and
wherein a distance between the second power amplifier and the second integrated circuit is shorter than a distance between the second power amplifier and the first integrated circuit.

2. The radio frequency module according to claim 1, wherein:
the first power amplifier is disposed adjacent to the first integrated circuit; and
the second power amplifier is disposed adjacent to the second integrated circuit.

3. The radio frequency module according to claim 1, further comprising:
a first module substrate,
wherein the first power amplifier, the second power amplifier, the voltage generation circuit, the first supply modulator, and the second supply modulator are arranged on or in the first module substrate, and
wherein the voltage generation circuit and the first integrated circuit are arranged on or in a second module substrate that is different from the first module substrate.

4. The radio frequency module according to claim 3, wherein the second integrated circuit is not arranged on or in the second module substrate.

5. The radio frequency module according to claim 1, wherein the first frequency band comprises at least one of a 5 GHz band, a 6 GHz band, and a 7 GHz band.

6. The radio frequency module according to claim 1, further comprising:
a third power amplifier configured to amplify a wireless local area network signal in a second frequency band that is lower than the first frequency band,
wherein the voltage generation circuit is configured to supply a voltage to the third power amplifier without passing through the first supply modulator and the second supply modulator.

7. The radio frequency module according to claim 6, wherein the second frequency band comprises a 2.4 GHz band.

8. The radio frequency module according to claim 6, wherein:
the first integrated circuit further includes at least one switch included in the voltage generation circuit; and
a distance between the first power amplifier and the first integrated circuit is shorter than a distance between the third power amplifier and the first integrated circuit.

9. The radio frequency module according to claim 6, wherein a distance between the second power amplifier and the second integrated circuit is shorter than a distance between the third power amplifier and the first integrated circuit.

10. The radio frequency module according to claim 1, further comprising a first digital pre-distortion circuit configured to pre-distort the wireless local area network signal in the first frequency band.

11. The radio frequency module according to claim 10, wherein the first digital pre-distortion circuit is disposed between the first power amplifier and the second power amplifier.

12. The radio frequency module according to claim 6, further comprising a second digital pre-distortion circuit configured to pre-distort the wireless local area network signal in the second frequency band.

13. A radio frequency module comprising:
a first power amplifier connected to a first antenna and configured to amplify a wireless local area network signal in a first frequency band;
a second power amplifier connected to a second antenna different from the first antenna and configured to amplify the wireless local area network signal in the first frequency band;
a voltage generation circuit configured to generate a plurality of discrete voltages;
a first supply modulator connected between the first power amplifier and the voltage generation circuit and configured to select and output at least one discrete voltage of the plurality of discrete voltages to the first power amplifier;
a second supply modulator connected between the second power amplifier and the voltage generation circuit and configured to select and output at least one discrete voltage of the plurality of discrete voltages to the second power amplifier;
a first integrated circuit including at least one switch included in the first supply modulator; and
a second integrated circuit including at least one switch included in the second supply modulator,
wherein a distance between the first power amplifier and the first integrated circuit is shorter than one-half of a distance between the first power amplifier and the second power amplifier, and
wherein a distance between the second power amplifier and the second integrated circuit is shorter than one-half of the distance between the first power amplifier and the second power amplifier.

14. The radio frequency module according to claim 13, wherein:
the first power amplifier is disposed adjacent to the first integrated circuit; and
the second power amplifier is disposed adjacent to the second integrated circuit.

15. The radio frequency module according to claim 13, further comprising:
a first module substrate,
wherein the first power amplifier, the second power amplifier, the voltage generation circuit, the first supply modulator, and the second supply modulator are arranged on or in the first module substrate, and
wherein the voltage generation circuit and the first integrated circuit are arranged on or in a second module substrate that is different from the first module substrate.

16. The radio frequency module according to claim 13, further comprising:
a third power amplifier configured to amplify a wireless local area network signal in a second frequency band that is lower than the first frequency band,
wherein the voltage generation circuit is configured to supply a voltage to the third power amplifier without passing through the first supply modulator and the second supply modulator.

17. The radio frequency module according to claim 16, wherein:
the first integrated circuit further includes at least one switch included in the voltage generation circuit; and
a distance between the first power amplifier and the first integrated circuit is shorter than a distance between the third power amplifier and the first integrated circuit.

18. The radio frequency module according to claim 16, wherein a distance between the second power amplifier and the second integrated circuit is shorter than a distance between the third power amplifier and the first integrated circuit.

19. The radio frequency module according to claim 13, further comprising a first digital pre-distortion circuit configured to pre-distort the wireless local area network signal in the first frequency band.

20. The radio frequency module according to claim 19, wherein the first digital pre-distortion circuit is disposed between the first power amplifier and the second power amplifier.
